(19) United States
(12) Patent Application Publication
(10) Pub. No.: US 2006/0216943 A1
(43) Pub. Date: Sep. 28, 2006

(54) Method for forming metal line

(76) Inventor: Yun-Seok Cho, Ichon-shi (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/322,002

(22) Filed: Dec. 30, 2005

(30) Foreign Application Priority Data
Mar. 22, 2005 (KR) 2005-0023519

(51) Int. Cl. H01L 21/302; H01L 21/461

(52) U.S. Cl. 438/754; 438/717

(57) ABSTRACT

A method for forming a metal line is provided. The method includes: forming a metal structure with a specific grain size on a substrate; forming a first hard mask layer on the metal structure; forming a second hard mask layer on the first hard mask layer; forming a photoresist pattern on the second hard mask layer; etching the second hard mask layer using the photoresist pattern as an etch barrier, thereby obtaining first hard masks; etching the first hard mask layer using the first hard masks as an etch barrier, thereby obtaining second hard masks; and etching the metal structure using the first hard masks as an etch barrier.

This application claims the benefit of priority of Korean patent application No. KR 2005-0023519, filed in the Korean Patent Office on Mar. 22, 2005, which is herein incorporated by reference in its entirety.

### TECHNICAL FIELD

The present invention relates to a method for fabricating a semiconductor device; and, more particularly, to method for forming a metal line in a semiconductor device.

### DESCRIPTION OF RELATED ARTS

A metal line process for forming a metal line in semiconductor device is important in semiconductor fabrication for ensuring the normal operation of the semiconductor device. However, as semiconductor devices have become more highly integrated and operated at low voltage levels, the implementation of the metal line process has become increasingly difficult.

FIG. 1 is a cross-sectional view illustrating a conventional process for forming a metal line.

A metal structure 105 is formed on a substrate 101. The metal structure 105 includes a barrier metal layer 102, an aluminum layer 103 and a titanium nitride layer 104 formed in sequential order. A photoresist layer 106 is formed on the metal structure 105, and is used in the patterning of the metal structure 105.

Although not illustrated, a photo-exposure and developing process is performed on the photoresist layer 106 to form a photo-resist pattern. Using the photoresist pattern as an etch barrier, the metal structure 105 is etched to form metal lines.

FIG. 2A is a micrographic image of a substrate structure formed by using a conventional metal line process.

Particularly, the illustrated metal lines are formed of aluminum and have a pitch of approximately 200 nm. As illustrated at ‘X’, the thickness of a photoresist pattern formed on a metal structure is not consistent, and the bottom surface of the photoresist pattern is rough. The bottom surface roughness occurs due to a specific grain characteristic of the metal structure.

FIG. 2B is a micrographic image illustrating photoresist patterns formed on a metal structure made by using a conventional metal line process. Due to the bottom surface roughness that may occur using a conventional metal line process, bridges, such as the bridges denoted at ‘Y’, may be generated between the photoresist patterns. The bridges are generated because the bottom surface of the photoresist pattern is uneven as a result of the grain characteristic of the metal. When the size of a photoresist pattern size is larger than the grain size of the metal, bridges are rarely generated. However, when micronized aluminum metal lines are formed, the grain characteristic may have an impact on the metal line process.

### SUMMARY

Consistent with the present invention there is provided a method for forming a metal line which may overcome the difficulties associated with patterning the metal line due to a specific grain characteristic of a metal according to a conventional metal line process.

Consistent with the present invention, there is provided a method for forming a metal line, including: forming a metal structure with a specific grain size on a substrate; forming a first hard mask layer on the metal structure; forming a second hard mask layer on the first hard mask layer; forming a photoresist pattern on the second hard mask layer; etching the second hard mask layer using the photoresist pattern as an etch barrier, thereby obtaining first hard masks; etching the first hard mask layer using the first hard masks as an etch barrier, thereby obtaining second hard masks; and etching the metal structure using the first hard masks as an etch barrier.

### BRIEF DESCRIPTION OF THE DRAWINGS

The invention will become better understood with respect to the following description of the embodiments given in conjunction with the accompanying drawings, in which:

FIG. 1 is a cross-sectional view illustrating a conventional method for forming a metal line;

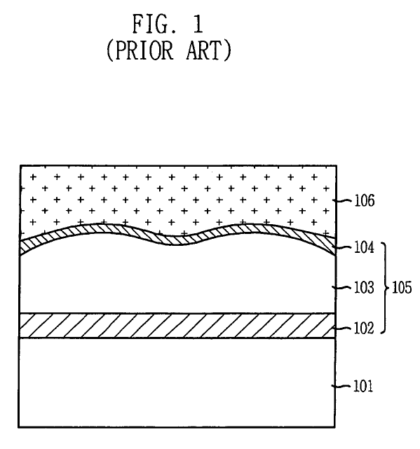

FIG. 2A is a micrographic image of a substrate structure after a conventional metal line process;

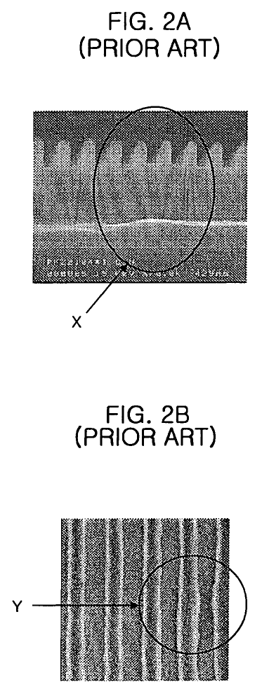

FIG. 2B is a micrographic image illustrating a bridge generation between photoresist patterns after a conventional metal line process; and

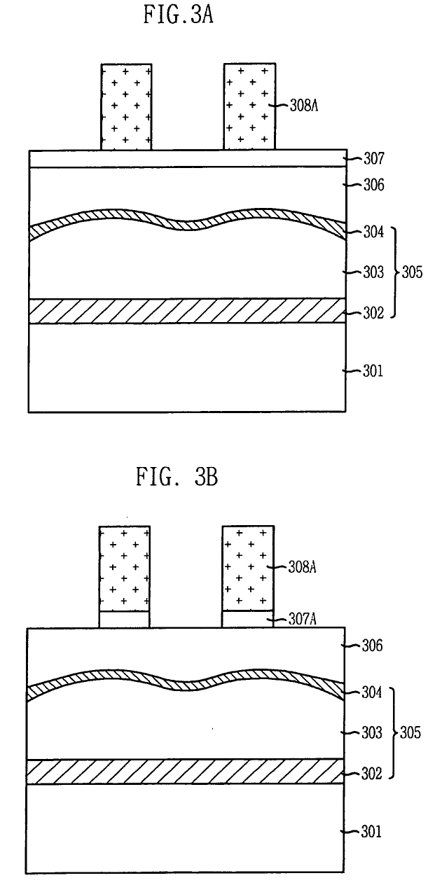

FIGS. 3A to 3D are cross-sectional views illustrating a method for forming a metal line consistent with an embodiment of the present invention.

### DETAILED DESCRIPTION

A method for forming a metal line consistent with exemplary embodiments of the present invention will be described in detail with reference to the accompanying drawings.

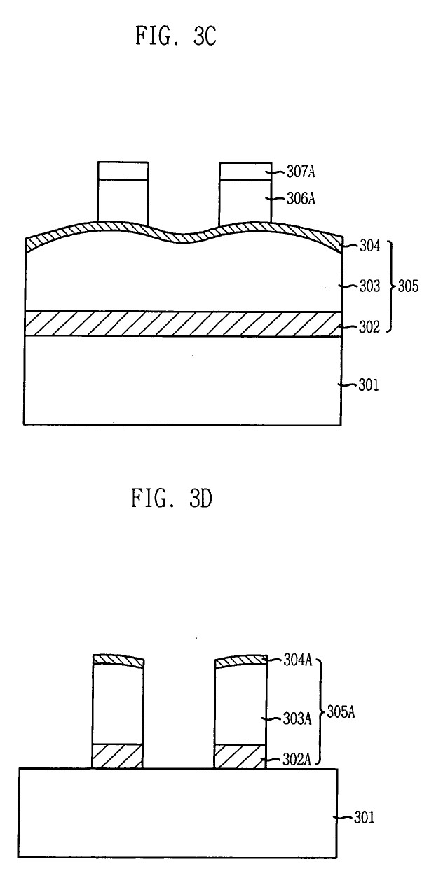

Referring to FIG. 3A, a metal structure 305 having a specific grain size is formed on a substrate 301. The metal structure 305 includes a barrier metal layer 302, an aluminum layer 303 and a titanium nitride layer 304 formed in sequential order. In addition to aluminum, metal structure 305 may include other metal-based materials such as tungsten. A first hard mask layer 306 is formed on the metal structure 305. First hard mask layer 306 is used to planarize the surface of the metal structure 305, which may be uneven due the specific grain size. The first hard mask layer 306 can be formed by the sequential steps of: spin coating an organic material or a carbon containing material; and then curing the spin coated material. The first had mask layer 306 may be cured at a temperature higher than a temperature for stabilizing a re-work process of a photoresist pattern but lower than a temperature at which deformation or a change in properties of the metal structure 305 occurs. The curing temperature may range from approximately 300° C. to approximately 500° C. The first hard mask layer 306 is formed to a certain thickness considering an etch selectivity between the metal structure 305 and the first hard mask layer 306.

A second hard mask layer 307 is formed on the first hard mask layer 306. The second hard mask layer 307 may be formed of SiON, SiHO or SiHON. The second hard mask layer 307 is formed to be a certain thickness determined by an etch selectivity between the first hard mask layer 306 and the second hard mask layer 307. Also, the second hard mask layer 307 may be formed of a material having an anti-reflective characteristic to a subsequent photoresist pattern. A photoresist pattern 308A used in the patterning of metal structure 305 is formed on the second hard mask layer 307.

Referring to FIG. 3B, using the photoresist pattern 308A as an etch barrier, the second hard mask layer 307 is etched to form first hard masks 307A.

Referring to FIG. 3C, using the first hard masks 307A as an etch barrier, the first hard mask layer 306 is etched to form second hard masks 306A. A plasma state of a gas including an O₂ or H₂ gas may be used in etching the first hard mask layer 306.

Referring to FIG. 3D, using the second hard masks 306A as an etch barrier, the metal structure 305 is etched to form a patterned metal structure 305A. The first hard masks 307A are then removed. The patterned metal structure 305A includes a patterned barrier metal layer 302A, a patterned aluminum layer 303A and a patterned titanium nitride layer 304A. Afterwards, the second hard masks 306A are removed.

In the present embodiment, as described above, the second hard masks 306A are formed by patterning the first hard mask layer 306. The first hard mask layer 306 is formed using a spin coating method which can eliminate any unevenness on the bottom portion of the photoresist pattern 308A caused by a grain characteristic of the metal structure 305. Since the first hard masks 307A are formed of an anti-reflective material, an additional anti-reflective coating layer is not necessary.

Since the bottom portion of the photoresist pattern is planarized, a margin for a photo-exposure and developing process can be increased and the thickness of the photoresist pattern can be reduced. Since an additional anti-reflective coating layer is not necessary, the entire fabrication process can be simplified.

While the present invention has been described with respect to certain preferred embodiments, it will be apparent to those skilled in the art that various changes and modifications may be made without departing from the spirit and scope of the invention as defined in the following claims.

What is claimed is:

1. A method for forming a metal line in a semiconductor device, comprising:
forming a metal structure on a substrate;
forming a first hard mask layer on the metal structure;
forming a second hard mask layer on the first hard mask layer;
forming a photoresist pattern on the second hard mask layer;
etching the second hard mask layer using the photoresist pattern as an etch barrier, to form first hard masks;
etching the first hard mask layer using the first hard masks as an etch barrier, to form second hard masks; and
etching the metal structure using the first hard masks as an etch barrier.

2. The method of claim 1, after the etching of the metal structure, further including the second hard masks.

3. The method of claim 1, wherein forming the first hard mask layer comprises:
spin coating a first hard mask material on the metal structure; and
curing the first hard mask material.

4. The method of claim 3, wherein the curing of the first hard mask material comprises curing at a temperature higher than a temperature for stabilizing a re-work process of the photoresist pattern but lower than a temperature at which the metal structure is deformed or a material property of the metal structure is changed.

5. The method of claim 4, wherein curing the first hard mask material comprises curing at a temperature of approximately 300° C. to approximately 500° C.

6. The method of claim 1, comprising removing the first hard masks when the metal structure is etched.

7. The method of claim 1, wherein forming the first hard mask layer comprises forming the first hard mask layer from a material including an organic material.

8. The method of claim 1, wherein forming the first hard mask layer comprises forming the first hard mask layer from a material including a carbon containing material.

9. The method of claim 1, wherein forming the second hard mask layer comprises forming the second hard mask layer from a material including an anti-reflective coating material.

10. The method of claim 1, wherein forming the second hard mask layer comprises forming the second hard mask from a material selected from the group consisting of SiON, SiHO and SiHON.

11. The method of claim 2, wherein etching the first hard mask layer comprises:
etching with a plasma gas including O₂ gas.

12. The method of claim 2, wherein etching the first hard mask layer comprises:
etching with a plasma gas including H₂ gas.

13. The method of claim 1, wherein forming the metal structure comprises:
sequentially forming a barrier metal layer, a metal layer, and a titanium nitride layer.

14. The method of claim 1, wherein forming the first hard mask layer further comprises:
forming the first hard mask layer to planarize an uneven profile of the metal structure.

15. The method of claim 13, wherein the metal layer includes aluminum or tungsten.
